(19) United States
(12) Patent Application Publication
(10) Pub. No.: US 2025/0102547 A1
(43) Pub. Date: Mar. 27, 2025

(54) OFFSET CORRECTION DEVICE AND OFFSET CORRECTION CIRCUIT

(71) Applicant: ISUZU MOTORS LIMITED, Yokohama-shi (JP)

(72) Inventors: Ryoma NISHIMURA, Fujisawa-shi (JP); Masashi ASASAKA, Fujisawa-shi (JP)

(21) Appl. No.: 18/822,820

(22) Filed: Sep. 3, 2024

(30) Foreign Application Priority Data
Sep. 22, 2023 (JP) 2023-159042

(51) Int. Cl. G01R 19/32

(52) U.S. Cl. CPC G01R 19/32

(57) ABSTRACT

An offset correction device includes: a first wiring portion; a second wiring portion; a switch portion that switches at least the second wiring portion to either a conductive state or a non-conductive state; and a control unit that controls the switch portion to perform offset correction of the sensor unit, in which the second wiring portion is disposed such that a current in a direction opposite to a current in the first wiring portion is measured by the sensor unit.

### TECHNICAL FIELD

The present disclosure relates to an offset correction apparatus and an offset correction circuit.

### BACKGROUND ART

It is known that a sensor unit capable of measuring a current is provided in a circuit that supplies current to a load. Since the measurement value in the sensor unit includes an offset value, offset correction is generally performed (see, for example, Patent Literature (hereinafter, referred to as PTL) 1). Generally, offset correction is performed when no current flows into the sensor unit.

### CITATION LIST

### Patent Literature

### PTL 1

Japanese Patent Application Laid-Open No. 2020-16493

### SUMMARY OF INVENTION

### Technical Problem

When a disturbance, a temperature change, or the like occurs during the operation of the load, however, an offset drift may occur, and an offset value based on the offset drift may be included in the measurement value of the sensor unit. In the conventional configuration, it has not been possible to perform offset correction when current flows into the sensor unit. For this reason, when a circuit is used such that a current continuously flows through the sensor unit, there arises a problem in that no opportunity for offset correction is obtained, leading to an increase in offset drift.

An object of the present disclosure is to provide an offset correction device and an offset correction circuit capable of suppressing an increase in offset drift, and further improving the measurement accuracy of a sensor unit.

### Solution to Problem

An offset correction device according to the present disclosure is for performing offset correction of a sensor unit, and the offset correction device includes: a first wiring portion that is connected to an input line and an output line and is disposed in a measurement region of the sensor unit; a second wiring portion that is connected in parallel to the first wiring portion and is disposed in the measurement region; a switch portion that switches at least the second wiring portion to either a conductive state or a non-conductive state; and a control unit that controls the switch portion to perform the offset correction of the sensor unit, in which the second wiring portion is disposed such that a current in a direction opposite to a current in the first wiring portion is measured by the sensor unit.

An offset correction circuit according to the present disclosure is for performing offset correction of a sensor unit, and the offset correction circuit includes: a first wiring portion that is connected to an input line and an output line and is disposed in a measurement region of the sensor unit; a second wiring portion that is connected in parallel to the first wiring portion and is disposed in the measurement region; and a switch portion that switches at least the second wiring portion to either a conductive state or a non-conductive state, in which the second wiring portion is disposed such that a current in a direction opposite to a current in the first wiring portion is measured by the sensor unit.

### Advantageous Effects of Invention

According to the present disclosure, it is possible to suppress an increase in the offset drift and further improve the measurement accuracy of the sensor unit.

### BRIEF DESCRIPTION OF DRAWINGS

FIG. 1 illustrates a schematic configuration of an offset correction device according to an embodiment of the present disclosure;

FIG. 2 illustrates the offset correction device in a first measurement state;

FIG. 3 illustrates the offset correction device in a second measurement state;

FIG. 4 is a flowchart illustrating an example of a flow of a process executed by the offset correction device according to the embodiment of the present disclosure;

FIG. 5 illustrates an offset correction device according to a variation; and

FIG. 6 illustrates an offset correction device according to another variation.

### DESCRIPTION OF EMBODIMENTS

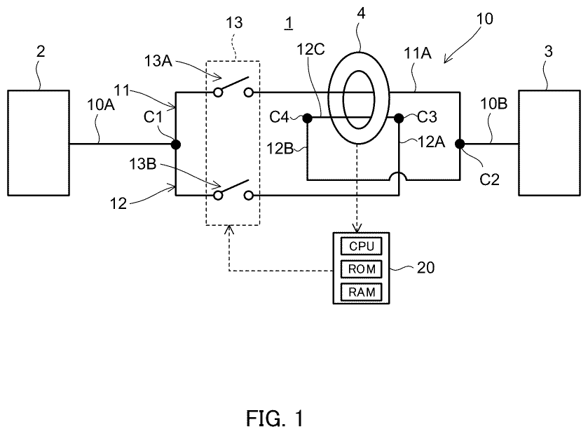

Hereinafter, embodiments of the present disclosure will be described in detail based on the drawings. FIG. 1 is a diagram illustrating the schematic configuration of offset correction device 1 according to an embodiment of the present disclosure.

As illustrated in FIG. 1, offset correction device 1 is a device capable of performing offset correction of sensor unit 4 provided in a power line connecting power supply 2 and load 3, for example.

Power supply 2 is, for example, a battery provided in a vehicle. Load 3 is, for example, a motor, an inverter, or the like provided in a vehicle, which is operable with electric power. Sensor unit 4 is a current sensor capable of measuring the current in the circuit and may be, for example, a Hall-type sensor, a shunt-type sensor, or another known configuration. FIG. 1 illustrates a Hall-type current sensor as sensor unit 4.

Offset correction device 1 includes offset correction circuit 10 and control unit 20.

Offset correction circuit 10 is a circuit provided at a position corresponding to sensor unit 4, and includes first wiring portion 11, second wiring portion 12, and switch portion 13.

First wiring portion 11 and second wiring portion 12 are power lines connected to input line 10A and output line 10B of offset correction circuit 10, and second wiring portion 12 is connected in parallel with first wiring portion 11. Input line 10A is a power line connected to power supply 2, and output line 10B is a power line connected to load 3.

Further, first wiring portion 11 includes first measurement portion 11A that is disposed in the measurement region of sensor unit 4. First measurement portion 11A is a portion that connects two connection points C1 and C2 between first wiring portion 11 and second wiring portion 12. Connection point C1 is connected to input line 10A, and connection point C2 is connected to output line 10B.

Further, sensor unit 4 is disposed in the region between connection point C1 and connection point C2, and the region where sensor unit 4 is disposed serves as the measurement region.

A part of first measurement portion 11A is disposed in the measurement region of sensor unit 4 such that a current flows in the direction from connection point C1 to connection point C2 (first direction). In other words, first measurement portion 11A of first wiring portion 11 is disposed such that the current in first wiring portion 11 is measured by sensor unit 4 as a current in the positive direction.

Second wiring portion 12 includes a first non-measurement portion 12A and a second non-measurement portion 12B that are disposed outside the measurement region of sensor unit 4 (non-measurement region), and second measurement portion 12C that is disposed in the measurement region of sensor unit 4. First non-measurement portion 12A and second non-measurement portion 12B correspond to the “two portions” of the present disclosure.

First non-measurement portion 12A is connected to connection point C1 on input line 10A side between first wiring portion 11 and second wiring portion 12 via second switch 13B described later. In the non-measurement region of sensor unit 4, first non-measurement portion 12A is disposed to connect connection point C1 and point C3. Point C3 is a point located on the side of connection point C2 with respect to the measurement region (sensor unit 4) and is connected to second measurement portion 12C to be described later.

Second non-measurement portion 12B is connected to connection point C2 on output line 10B side, connection point C2 being a connection point between first wiring portion 11 and second wiring portion 12. In a non-measurement region of sensor unit 4, second non-measurement portion 12B is disposed to connect point C4 and connection point C2. Point C4 is a point that is located on the side of connection point C1 with respect to the measurement region (sensor unit 4) and is a point connected to second measurement portion 12C to be described later.

Second measurement portion 12C is disposed between point C3 of first non-measurement portion 12A and point C4 of second non-measurement portion 12B such that second measurement portion 12C passes through the measurement region. That is, first non-measurement portion 12A and second non-measurement portion 12B are each connected to both sides of the portion corresponding to the measurement region in second measurement portion 12C.

The current flowing through second measurement portion 12C flows in a direction toward point C4 of second non-measurement portion 12B from point C3 of first non-measurement portion 12A. That is, second measurement portion 12C is disposed such that a current flows in the second direction, which is opposite to the first direction described above. In other words, second wiring portion 12 is disposed such that a current in a direction opposite to the current in first wiring portion 11 (current in the negative direction) is measured in sensor unit 4.

Thus, second measurement portion 12C is disposed such that the current in second wiring portion 12 is measured by sensor unit 4 as a current in the negative direction. As a result, when both first wiring portion 11 and second wiring portion 12 are conductive, sensor unit 4 outputs the difference between the absolute value of the current in first wiring portion 11 and the absolute value of the current in second wiring portion 12 as the measurement value.

Switch portion 13 is a group of switches for switching each of first wiring portion 11 and second wiring portion 12 to either a conductive state or a non-conductive state, and includes first switch 13A and second switch 13B. First switch 13A and second switch 13B may be, for example, a semiconductor switching element such as a Field Effect Transistor (FET).

First switch 13A is a switch that switches first wiring portion 11 to either a conductive state or a non-conductive state. Second switch 13B is a switch that switches second wiring portion 12 to either a conductive state or a non-conductive state.

Further, first switch 13A and second switch 13B have the same impedance. That is, the impedance of second wiring portion 12 is equal to the impedance of first wiring portion 11. For this reason, when both first wiring portion 11 and second wiring portion 12 are conductive, the absolute value of the current in first wiring portion 11 is identical to the absolute value of the current in second wiring portion 12.

Note that the impedance of second wiring portion 12 being equal to the impedance of first wiring portion 11 includes not only the case where the two impedances completely match each other, but also the case where the difference between the two impedances is a minute value due to a difference in wiring resistance.

Control unit 20 is, for example, an electronic control unit (ECU) provided in a vehicle, and includes a central processing unit (CPU), a read only memory (ROM), and a random access memory (RAM), and an input/output circuit (not illustrated). Control unit 20 controls switch portion 13 to perform offset correction of sensor unit 4.

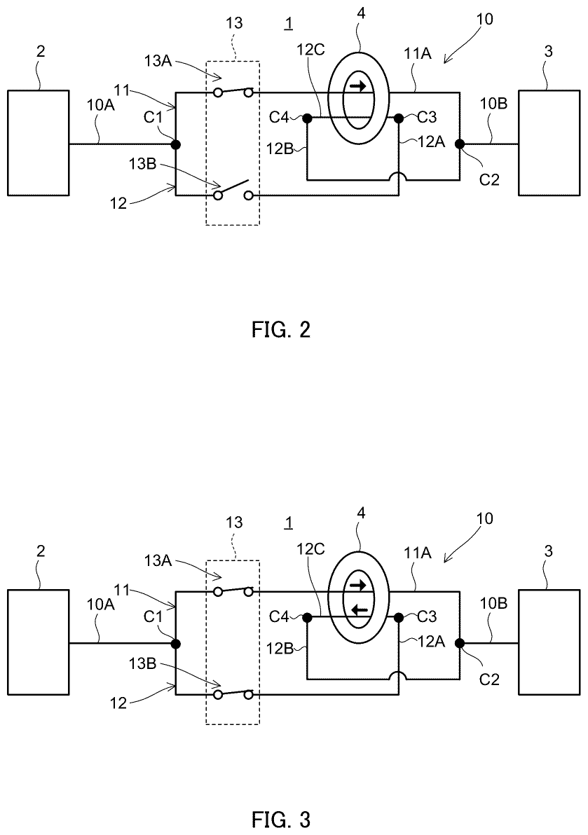

As illustrated in FIG. 2, control unit 20 controls switch portion 13 such that a first measurement state is set, the first measurement state being a state in which first wiring portion 11 is brought into conductive and second wiring portion 12 is brought into non-conductive. Specifically, control unit 20 controls first switch 13A such that first wiring portion 11 is conductive, and controls second switch 13B such that second wiring portion 12 is non-conductive. The first measurement state is a state in which only the current flowing through first wiring portion 11 is measured by sensor unit 4.

A current is continuously supplied to load 3 in the state where the first measurement state is set, and then an offset drift occurs in the measurement value of sensor unit 4 due to disturbances, temperature changes during vehicle operation, or the like. Since the measurement value of sensor unit 4 originally includes an offset value, offset correction is generally performed in advance. Normally, the offset correction is performed when no current flows through sensor unit 4.

However, when load 3 is used such that a current is continuously supplied, an offset drift occurs as described above, and an offset value due to the offset drift is included in the measurement value of sensor unit 4. Thus, the value may differ from the actual current value supplied to load 3.

In the present embodiment, control unit 20 performs offset correction based on the measurement state of sensor unit 4 in the first measurement state. Specifically, control unit 20 determines whether the latest measurement value of sensor unit 4 in the first measurement state varies from the initial measurement value of sensor unit 4 when the first measurement state is set.

Then, in a case where control unit 20 determines that the latest measurement value has varied from the initial measurement value, control unit 20 controls switch portion 13 such that the second measurement state, in which first wiring portion 11 and second wiring portion 12 are conductive, is set. Specifically, as illustrated in FIG. 3, control unit 20 controls first switch 13A to make first wiring portion 11 conductive, and controls second switch 13B to make second wiring portion 12 conductive. The second measurement state is a state in which sensor unit 4 measures the current flowing through first wiring portion 11 and the current flowing through second wiring portion 12.

As described above, when both first wiring portion 11 and second wiring portion 12 are conductive, sensor unit 4 outputs the difference between the absolute value of the current in first wiring portion 11 and the absolute value of the current in second wiring portion 12 as a measurement value. In addition, as described above, the absolute value of the current in first wiring portion 11 is the same as the absolute value of the current in second wiring portion 12.

For this reason, when the second measurement state is set, the current in first wiring portion 11 and the current in second wiring portion 12 offset each other, and only the measurement value of the offset current based on the offset drift is measured by sensor unit 4. That is, when the second measurement state is set, the offset current can be measured by sensor unit 4.

Control unit 20 performs offset correction based on the measurement result of sensor unit 4 in the second measurement state. Specifically, control unit 20 defines the value obtained by subtracting the measurement value of the offset current from the measurement value of sensor unit 4 before the offset correction as a measurement value of sensor unit 4 after the offset correction.

Thus, in a case where the circuit is used such that a current continues to flow through sensor unit 4 at all times, an opportunity for offset correction is obtained, and it is possible to suppress the occurrence of offset drift.

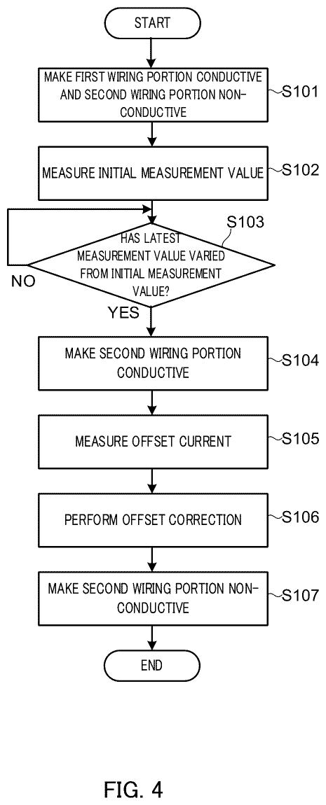

Next, the operation of offset correction device 1 will be described. FIG. 4 is a flowchart illustrating an example of the process flow executed by offset correction device 1 according to the present embodiment. The processing in FIG. 4 is executed when a vehicle including offset correction device 1 starts operating.

As illustrated in FIG. 4, control unit 20 makes first wiring portion 11 conductive and second wiring portion 12 non-conductive (step S101). That is, control unit 20 controls switch portion 13 such that the first measurement state is set.

After step S101, control unit 20 measures the initial measurement value with sensor unit 4 (step S102). After measuring the initial measurement value, control unit 20 monitors the measurement value from sensor unit 4 and determines whether the latest measurement value has varied from the initial measurement value (step S103). Note that the processing in step S103 may be executed each time a certain time elapses.

In a case where the determination result is that the latest measurement value does not vary from the initial measurement value (step S103, NO), the process in step S103 is repeated. In a case where the latest measurement value varies from the initial measurement value (step S103, YES), control unit 20 makes second wiring portion 12 conductive (step S104). That is, control unit 20 controls switch portion 13 such that the second measurement state is set.

Then, control unit 20 measures the offset current using sensor unit 4 (step S105). After step S105, control unit 20 executes offset correction based on the measurement value of the offset current (step S106).

After step S106, control unit 20 causes second wiring portion 12 to be in a non-conductive state (step S107). That is, control unit 20 controls switch portion 13 such that the first measurement state is set. Note that the processing in step S107 may be executed at any timing as long as it is after the processing in step S105, in which the offset current is measured.

After Step S107, the present control ends. Note that, after the processing in step S107, the processing may return to step S102.

According to the present embodiment configured as described above, second wiring portion 12 is disposed such that a current in the direction opposite to the current in first wiring portion 11 is measured by sensor unit 4. Specifically, first wiring portion 11 includes first measurement portion 11A disposed such that a current flows in a first direction, and second wiring portion 12 includes second measurement portion 12C disposed such that a current flows in a second direction, which is opposite to the first direction.

Thus, when a current flows through both first wiring portion 11 and second wiring portion 12, sensor unit 4 can measure the current value obtained by subtracting the current of second wiring portion 12 from the current of first wiring portion 11.

As a result, it is possible to facilitate the measurement of the offset value by sensor unit 4 when an offset drift occurs, and thus, it is possible to perform offset correction even while a current continues to flow through the circuit. That is, in the present embodiment, it is possible to suppress the increase in offset drift and further improve the measurement accuracy of sensor unit 4.

Further, since first wiring portion 11 and second wiring portion 12 are connected in parallel, there is little influence on the current supplied to load 3 even when current flows through both first wiring portion 11 and second wiring portion 12. For this reason, it is possible to perform offset correction while continuing to supply current to the circuit.

Further, control unit 20 sets the first measurement state where first wiring portion 11 is conductive and second wiring portion 12 is non-conductive, and sets the second measurement state where both first wiring portion 11 and second wiring portion 12 are conductive based on the measurement result of sensor unit 4 in the first measurement state. Thus, by detecting the occurrence of offset drift by the variation in the measurement value of sensor unit 4 in the first measurement state, it is possible to switch to the second measurement state and quickly detect the offset value.

That is, by controlling switch portion 13, it is possible to quickly detect the offset value while continuing to supply current to the circuit, thereby achieving a simple configuration and enabling simple control.

Further, since the impedance of second wiring portion 12 is equal to the impedance of first wiring portion 11, the measurement value of sensor unit 4 can be used as an offset value when a current flows through both first wiring portion 11 and second wiring portion 12. As a result, the measurement of the offset value can be facilitated.

Further, input line 10A is connected to power supply 2 of the vehicle, and output line 10B is connected to load 3 of the vehicle. When a vehicle travels, the temperature around the vehicle may change due to changes in the surrounding environment. Thus, offset drift is likely to occur in some cases. Since a vehicle often continues to operate, it is necessary to frequently perform the offset correction. In particular, in the case of a commercial vehicle, the bodywork often continues to operate even when the vehicle is not being driven, thus increasing the necessity of performing offset correction frequently.

In the present embodiment, it is possible to perform offset correction while continuing to supply current to the circuit. Thus, when the device is mounted in a vehicle, it is possible to perform the offset correction in a timely manner, thereby easily improving the measurement accuracy of sensor unit 4.

Note that, in the above embodiment, the wiring resistances of first wiring portion 11 and second wiring portion 12 were not particularly considered. Specifically, in the above embodiment, second wiring portion 12, which includes first non-measurement portion 12A, second non-measurement portion 12B, and second measurement portion 12C, was longer in length and had a larger wiring resistance than first wiring portion 11. However, the present disclosure is not limited thereto, and the wiring resistances of first wiring portion 11 and second wiring portion 12 may be configured to be equal to each other.

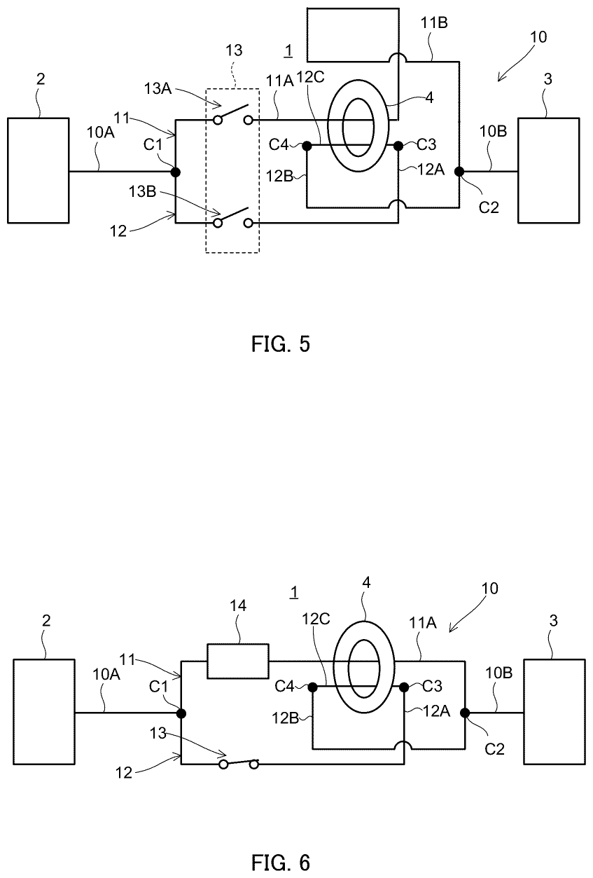

For example, as illustrated in FIG. 5, first wiring portion 11 may include non-measurement portion 11B that is connected to the latter portion of sensor unit 4 in first measurement portion 11A. Non-measurement portion 11B is disposed in a non-measurement region of sensor unit 4 and has a length such that the wiring resistance of first wiring portion 11 is equal to the wiring resistance of second wiring portion 12.

Thus, it is possible to match the impedance of first wiring portion 11 and second wiring portion 12, thereby enabling more accurate offset correction.

Further, in the above embodiment, first switch 13A is provided in first wiring portion 11, and second switch 13B is provided in second wiring portion 12. That is, in the above embodiment, control was performed so that first wiring portion 11 was in a conductive state in both the first measurement state and the second measurement state, but the present disclosure is not limited thereto.

For example, as illustrated in FIG. 6, switch portion 13 (a single switch) may be provided only in second wiring portion 12. In this case, in order to equalize the impedance of each of first wiring portion 11 and second wiring portion 12, for example, some circuit element 14 (for example, a resistance element, a switching element fixed in a conduction state, or the like) may be provided in first wiring portion 11. Note that, in this configuration, another switch may be provided on input line 10A or output line 10B in order to cut off the supply of electric power when the operation of load 3 is stopped.

Further, in the above embodiment, sensor unit 4 measures the current in first wiring portion 11 as a positive current and measures the current in second wiring portion 12 as a negative current, but the present disclosure is not limited thereto. For example, the sensor unit may measure the current in the first wiring portion as a negative current and the current in the second wiring portion as a positive current.

Further, in the above embodiment, offset correction device 1 is mounted on a vehicle, but the present disclosure is not limited to this, and offset correction device 1 may be mounted on an object other than a vehicle. As the object other than a vehicle, any object including a load operable with electric power may be acceptable. Further, for example, when an offset correction device is provided in a facility such as a factory or a building, where a load needs to continue operating, it is considered that the offset correction can be performed while the load is operating, thereby likely contributing to an improvement in the measurement accuracy of the sensor unit.

The embodiments above are no more than specific examples in carrying out the present disclosure, and the technical scope of the present disclosure is not to be construed in a limitative sense due to the specific examples. That is, the present disclosure can be implemented in various forms without departing from its spirit or key features.

This application is entitled to and claims the benefit of Japanese Patent Application No. 2023-159042, filed on Sep. 22, 2023, the disclosure of which including the specification, drawings and abstract is incorporated herein by reference in its entirety.

### INDUSTRIAL APPLICABILITY

The offset correction device of the present disclosure is useful as an offset correction device and an offset correction circuit capable of suppressing an increase in offset drift, thereby improving the measurement accuracy of a sensor unit.

1. An offset correction device for performing offset correction of a sensor unit, the offset correction device comprising:
a first wiring portion that is connected to an input line and an output line and is disposed in a measurement region of the sensor unit;
a second wiring portion that is connected in parallel to the first wiring portion and is disposed in the measurement region;
a switch portion that switches at least the second wiring portion to either a conductive state or a non-conductive state; and
a control unit that controls the switch portion to perform the offset correction of the sensor unit, wherein
the second wiring portion is disposed such that a current in a direction opposite to a current in the first wiring portion is measured by the sensor unit.

2. The offset correction device according to claim 1, wherein
the first wiring portion includes a first measurement portion disposed in the measurement region and disposed such that a current flows in a first direction, and
the second wiring portion includes:
a second measurement portion disposed in the measurement region and disposed such that a current flows in a second direction, which is opposite to the first direction; and
two portions respectively connected to both sides of a portion in the second measurement portion corresponding to the measurement region.

3. The offset correction device according to claim 2, wherein
one of the two portions is connected to a connection point between the first wiring portion and the second wiring portion on an input line side, and
the other of the two portions is connected to a connection point between the first wiring portion and the second wiring portion on an output line side.

4. The offset correction device according to claim 1, wherein
the control unit
controls the switch portion such that a first measurement state is set, the first measurement state being a state in which the second wiring portion is in a non-conductive state,
controls the switch portion such that a second measurement state is set, based on a measurement result of the sensor unit in the first measurement state, the second measurement state being a state in which the second wiring portion is in a conductive state, and
performs the offset correction based on the measurement result of the sensor unit in the second measurement state.

5. The offset correction device according to claim 4, wherein
the switch portion includes a first switch that switches the first wiring portion to either a conductive state or a non-conductive state, and a second switch that switches the second wiring portion to either a conductive state or a non-conductive state, and
the control unit controls the switch portion such that the first wiring portion is in the conductive state in the first measurement state and the second measurement state.

6. The offset correction device according to claim 1, wherein
an impedance of the second wiring portion is equal to an impedance of the first wiring portion.

7. The offset correction device according to claim 1, wherein
the input line is connected to a power supply of a vehicle, and
the output line is connected to a load of the vehicle.

8. An offset correction circuit for performing offset correction of a sensor unit, the offset correction circuit comprising:
a first wiring portion that is connected to an input line and an output line and is disposed in a measurement region of the sensor unit;
a second wiring portion that is connected in parallel to the first wiring portion and is disposed in the measurement region; and
a switch portion that switches at least the second wiring portion to either a conductive state or a non-conductive state, wherein
the second wiring portion is disposed such that a current in a direction opposite to a current in the first wiring portion is measured by the sensor unit.
